(19) United States
(12) Patent Application Publication
(10) Pub. No.: US 2008/0081462 A1
(43) Pub. Date: Apr. 3, 2008

(54) METHOD FOR FABRICATING SEMICONDUCTOR DEVICE

(75) Inventor: Se-Kyoung CHOI, Ichon-shi (KR)

Correspondence Address: LOWE HAUPTMAN HAM & BERNER, LLP, 1700 DIAGONAL ROAD, SUITE 300, ALEXANDRIA, VA, 22314, US

(73) Assignee: HYNIX SEMICONDUCTOR INC., Ichon-shi (KR)

(21) Appl. No.: 11/770,879

(22) Filed: Jun. 29, 2007

(30) Foreign Application Priority Data
Sep. 28, 2006 (KR) 10-2006-0095060

(51) Int. Cl. H01L 21/4763; H01L 21/469

(52) U.S. Cl. 438/637; 438/763; 257/E21.495; 257/E21.487

(57) ABSTRACT

A method for fabricating a semiconductor device includes forming a plurality of memory cells and transistors over a substrate, forming a first stopping layer having tensile stress over the plurality of memory cells and transistors, forming a first insulation layer over the substrate and the first stopping layer, and forming a second stopping layer having compression stress over the first insulation layer.

### CROSS-REFERENCE TO RELATED APPLICATIONS

The present invention claims priority of Korean patent application number 2006-0095060, filed on Sep. 28, 2006 which is incorporated by reference in its entirety.

### BACKGROUND OF THE INVENTION

The present invention relates to a method for fabricating a semiconductor memory device, and more particularly, to a method for fabricating a non-volatile memory device including a NAND flash memory device.

A semiconductor memory is usually classified into a volatile memory, where stored information is erased upon stoppage of power supply, and a non-volatile memory, where stored information is retained despite of the stoppage of power supply. The non-volatile memory includes an erasable programmable read only memory (EPROM), an electrically EPROM (EEPROM), and a flash memory.

The flash memory is distinguished into a NOR type and a NAND type according to the cell configuration. A cell array of a NAND memory includes a plurality of strings, each connected with 16 or 32 memory cells. Each of the strings includes a drain selection transistor, a plurality of memory cells and a source selection transistor, which are connected in series. An impurity region adjacent to the drain selection transistor is connected with a bit line, and an impurity region adjacent to a ground selection transistor is connected with a common source line.

FIG. 1 is a cross-sectional view illustrating a conventional method for fabricating a NAND flash memory device. A P-type substrate 10 includes a cell region CELL and a peripheral region PERI. A triple N-type well, a deep P-type well and a shallow P-type well are formed in the cell region CELL (not shown). An N-type well 14 is formed in the peripheral region PERI. A plurality of gate pattern is formed over the substrate 10. For example, first gate patterns SSL for a source selection transistor, second gate patterns CL for memory cells and a third gate pattern DSL for a drain selection transistor are formed over the cell region CELL. A fourth gate pattern LVP for a low voltage transistor is formed over peripheral region PERI. Each of the first to fourth gate patterns SSL, CL, DSL, and LVP has a structure laminated sequentially with a tunnel oxide layer 15, a floating gate 16, a dielectric layer 17, a control gate 18, a silicide layer 19, and a capping layer 20.

First source/drain regions 21A are formed by implanting a P-type impurity into an exposed portion of the substrate 10 on both sides of the fourth gate pattern LVP. Second source/drain regions 21B are formed by implanting N-type impurity into an active region of the substrate 10 using the first to third gate patterns SSL, CL and DSL as an ion implantation mask. Among the second source/drain regions 21B, a group of the second source/drain regions 21B adjacent to the first gate patterns SSL corresponds to a common source region of a ground selection transistor, and one of the second source/drain regions 21B adjacent to the third gate pattern DSL corresponds to a drain region of the drain selection transistor.

A sidewall protection layer 22 is formed on both sidewalls of the first to third gate patterns SSL, CL and DSL. A portion of the fourth gate pattern LVP formed over the substrate 10 of the peripheral region PERI is etched to form an opening (not shown). At this time, the opening is formed to expose a part of the floating gate 16.

A first stopping layer 23 is deposited over the above resultant surface profile including the opening. The first stopping layer 23 is formed of an insulation material having an etch selectivity ratio to an insulation layer 24 to be formed in the following process. One example of the insulation material is silicon nitride. A silicon nitride layer may be deposited using a plasma enhanced-chemical vapor deposition (PE-CVD) method.

The aforementioned first insulation layer 24 is formed over the first stopping layer 23. The first insulation layer 24 and the first stopping layer 23 are etched to form a source contact hole (not shown) that exposes the source region of the source selection transistors. At the same time, a drain contact hole (not shown) that exposes the drain region of the drain selection transistor is formed. A source contact plug 25A functioning as the common source line and a drain contact plug 25B are formed in the source contact hole and the drain contact hole, respectively.

A second insulation layer 27 and a second stopping layer 28 are formed over the first insulation layer 24, and the source and drain contact plugs 25A and 25B where the source contact plug 25A and the drain contact plug 25B are formed. The second stopping layer 28 is formed using an insulation material, which has an etch selectivity ratio to a third insulation layer 29 to be formed in the following process. For example, the insulation material is silicon nitride. A Silicon nitride layer is deposited by a PE-CVD method.

The third insulation layer 29 is formed over the second stopping layer 28. Metal lines and a bit line are formed through a dual damascene process.

The third insulation layer 29 is formed over the second stopping layer 28. The third insulation layer 29, the second stopping layer 28 and the second insulation layer 27 disposed in the cell region CELL are patterned through the damascene process. Subsequently, openings (not shown) including a via hole and a trench respectively exposing the source contact plug 25A and the drain contact plug 25B are formed. Further, the dual damascene process is performed on the third insulation layer 29, the second stopping layer 28, the second insulation layer 27, the first insulation 24, and the first stopping layer 23 disposed in the peripheral region PERI to form openings including via holes exposing the respective first source/drain regions 21A and a trench exposing the fourth gate pattern LVP.

A barrier layer 30 is deposited over the resultant surface profile obtained after the formation of the openings by the dual damascene process. The barrier layer 30 is a refactory metal-based layer or a metal nitride layer, which can prevent diffusion of copper. The barrier layer 30 prevents diffusion of metal in a subsequent metal layer 31 and strengthens adhesion with the first to third insulation layers 24, 27 and 29.

The metal layer 31 is formed over the barrier layer 30 to fill the above openings (now shown) formed by the dual damascene process. The metal layer 31 and the barrier layer 30 are chemically planarized by a specific treatment, for example, chemical mechanical polishing (CMP), to form a plurality of first metal lines 33A, 33C, 33D, and 33E and a bit line 33B. The first metal line 33A is electrically connected with the source contact plug 25A, arranged in parallel to bit line 33B, and connects the source contact plug 25A to the peripheral region PERI.

A third stopping layer 34 and a fourth insulation layer 35 are deposited subsequently over the third insulation layer 29 including the first metal lines 33A, 33C, 33D, and 33E and the bit line 33B. The third stopping layer 34 is formed of a silicon nitride layer and deposited by a PE-CVD method like the first and second stopping layers 23 and 28. The fourth insulation layer 35 and the third stopping layer 34 are etched to form openings (now shown) exposing the first metal lines 33A and 33E and the bit line 33B. A plurality of second metal lines 39 fill the openings formed by the above etching. At this time, each of the second metal lines 39 is formed in a structure laminated with another barrier layer 37 and another metal layer 38.

However, when the silicon nitride layer used as the stopping layer is deposited by the PE-CVD method, a thin film formed over memory cells and transistors may have compressive stress, which decreases charge mobility in the transistors. The correlation characteristic between this compression stress and the charge mobility is described in an article, entitled “MOSFET Current Drive Optimization Using Silicon Nitride Capping Layer for 65-nm Technology Node,” Symposium on VLSI Technology, pp. 54-55, 2004.

Particularly, the decrease in charge mobility of a transistor causes a decrease in GM (i.e., Δ Id (drain current)/Δ Vg (gate voltage)) and an increase in threshold voltage change, further resulting in degradation of device characteristics. For reference, a composition ratio of a silicon nitride layer often determines stress of the layer. A silicon nitride layer formed by a PE-CVD method has compressive stress according to the composition ratio of the layer. Here, the composition ratio of the layer is determined according to input power, substrate temperature and a gas mixture ratio applied when the layer formed is usually thin.

### SUMMARY OF THE INVENTION

The present invention contemplates a method for fabricating a semiconductor device to improve device characteristic by preventing a decrease in charge mobility of a transistor due to compressive stress exerted to a transistor from a thin layer formed over a memory cell and a transistor.

In accordance with an embodiment of the present invention, there is provided a method for fabricating a semiconductor device. The method includes forming a plurality of memory cells and transistors over a substrate, forming a first stopping layer having tensile stress over the plurality of memory cells and transistors, forming a first insulation layer over the substrate and the first stopping layer, and forming a second stopping layer having compression stress over the first insulation layer.

In accordance with another embodiment of the present invention, there is provided a method for fabricating a semiconductor device. The method includes forming a plurality of memory cells and transistors over a substrate, forming a first nitride-based layer having tensile stress over the plurality of memory cells and transistors, the first nitride-based layer formed by a low pressure chemical vapor deposition method, forming a first insulation layer over the substrate and the first stopping layer, and forming a second nitride-based layer having compression stress over the first insulation layer, the second nitride-based layer formed by a plasma enhanced chemical vapor deposition method, wherein the first and second nitride-based layers have an etch selectivity ratio to the first insulation layer.

### BRIEF DESCRIPTION OF THE DRAWINGS

FIG. 1 is a cross-sectional view showing a method for fabricating a conventional NAND flash memory device.

FIGS. 2A to 2C are cross-sectional views showing a method for fabricating a NAND flash memory device accorded to an embodiment of the present invention.

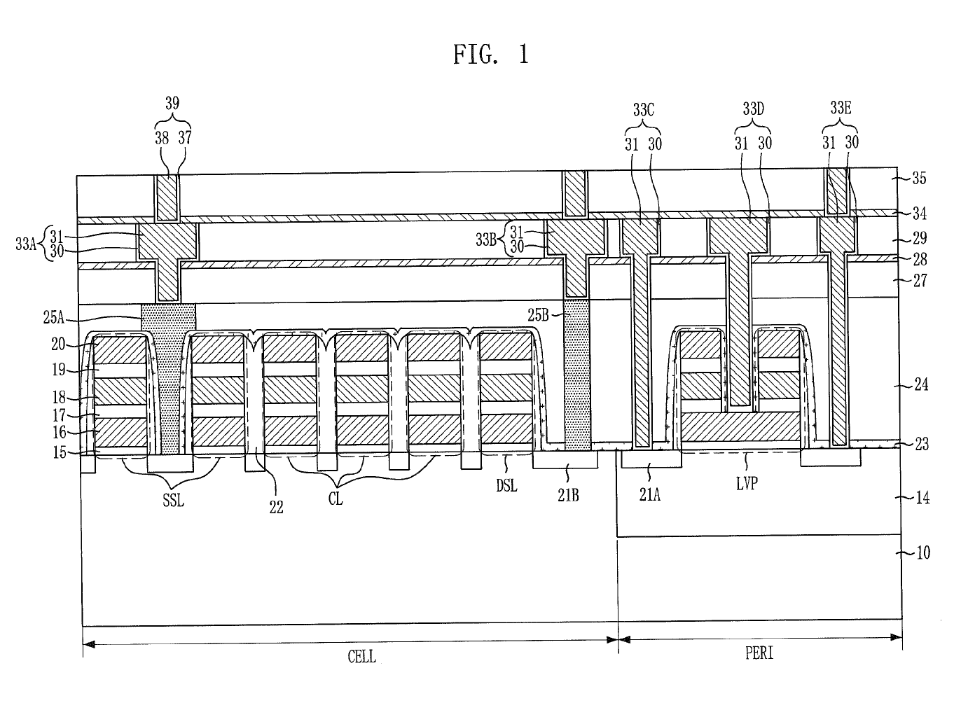

### DESCRIPTION OF SPECIFIC EMBODIMENTS

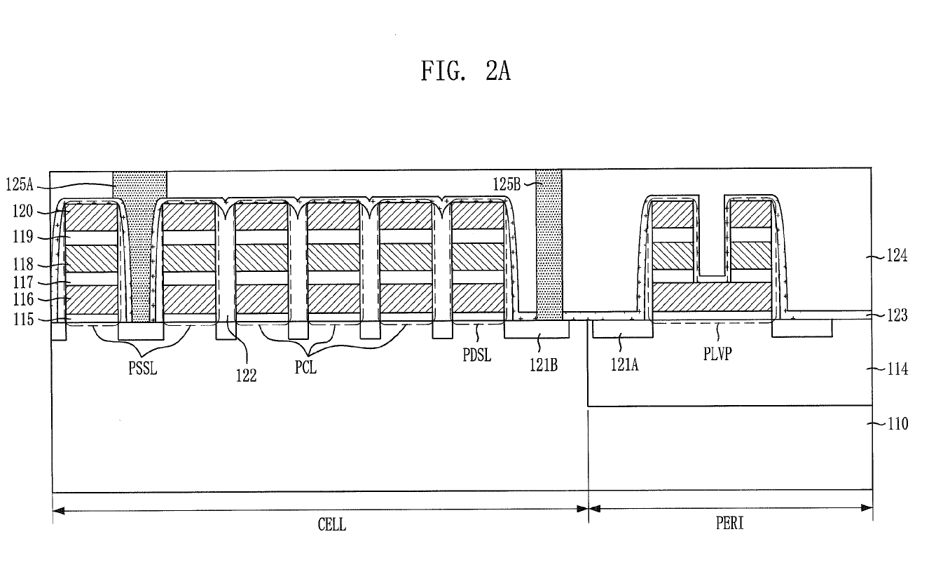

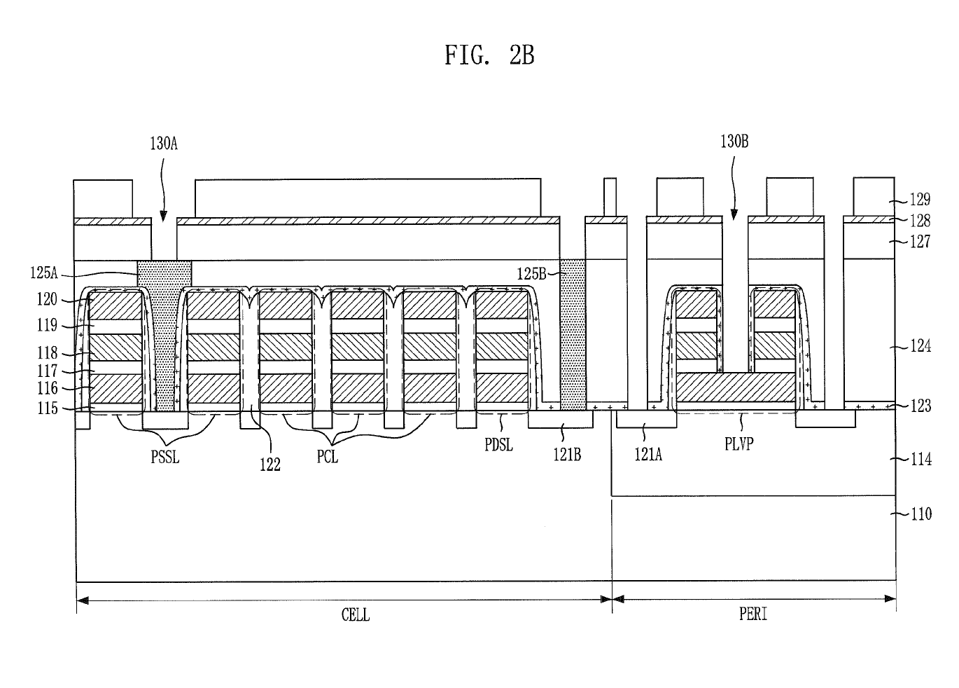

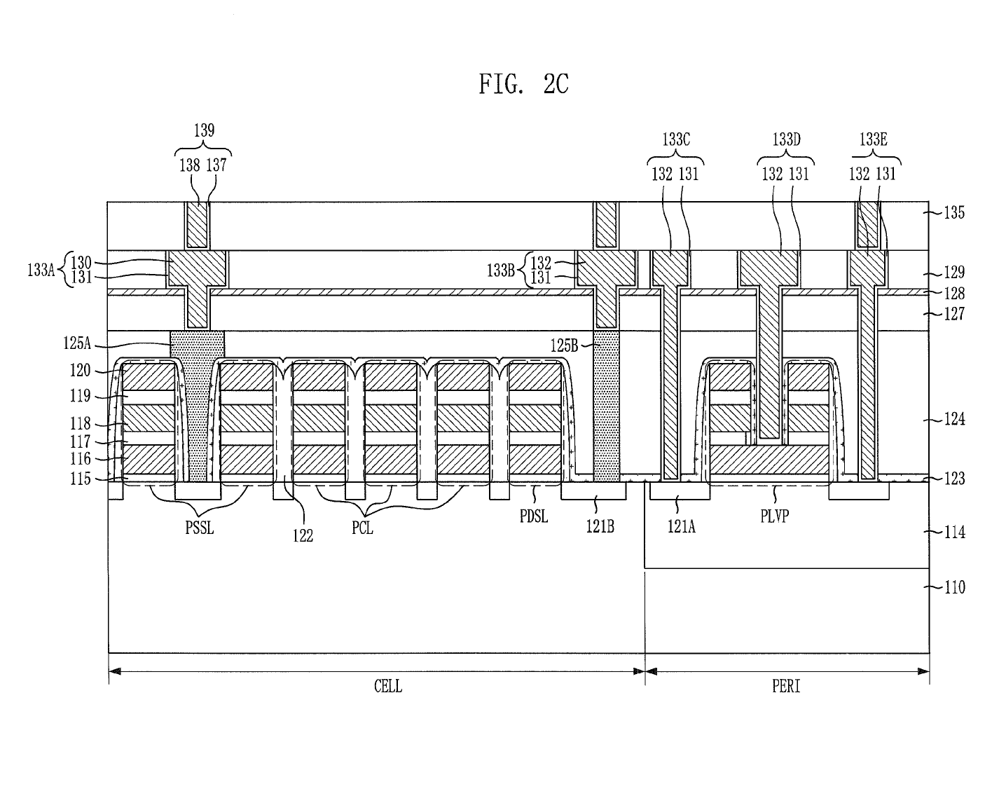

Referring to FIG. 2A, a substrate 110 (e.g., P-type substrate), which includes a cell region CELL and a peripheral region PERI, is provided. A triple N-type well, a deep P-type well and a shallow P-type well are formed in the cell region CELL, and an N-type well 114 is formed in the peripheral region PERI. A plurality of gate patterns for transistors are formed over the substrate 110. For example, first gate patterns PSSL for first transistors used to select one junction region (e.g. source region), second gate patterns PCS for memory cells and a third gate pattern PDSL for a second transistor used to select another junction region (e.g., drain region) are formed over the cell region CELL. A fourth gate pattern PLVP for a low voltage transistor is formed in the peripheral region PERI. Each of the first to fourth gate patterns PSSL, PCL, PDSL, and PLVP includes a structure laminated with a tunnel oxide layer 115, a floating gate 116, a dielectric layer 117, a control gate 118, a silicide layer 119, and a capping layer 120.

In the present embodiment, the two first gate patterns PSSL are illustrated because, two adjacent first transistors configured in the respective strings in a memory cell array are shown separately. Although, three second gate patterns PCL are illustrated, this number can be altered according to a string layout. For example, in a 16 string structure, 16 memory cells are prepared per unit cell, and in a 32 string structure, 32 memory cells are prepared per unit cell.

First junction regions 121A (i.e., source/drain regions) are formed by implanting a P-type impurity into the substrate 110 exposed on both sides of the fourth gate pattern PLVP. An N-type impurity is implanted into an active region of the substrate 110 using the first gate patterns PSSL, the second gate pattern PCL and the third gate pattern PDSL as a mask to form second junction regions 121B (i.e., source/drain regions).

Among the second junction regions 121B, a group of the second junction regions 121B adjacent to the first gate patterns PSSL corresponds to a common source region of a ground selection transistor, and one of the second junction regions 121B adjacent to the third gate pattern PDSL corresponds to a drain region of the second selection transistor.

A sidewall protection layer 122 is formed on sidewalls of the first to third gate patterns PSSL, PCL and PDSL. A part of the fourth gate pattern PLVP is etched to form a first opening 200. At this time, the first opening 200 is formed in a manner to expose a part of the floating gate 116.

A first stopping layer 123 is formed over the resultant surface profile including the first opening. The first stopping layer 123 includes an insulation material having an etch selectivity ratio to a first insulation layer 124 to be formed later. For instance, the first stopping layer 123 includes a nitride-based layer, more specifically, a silicon nitride layer. It is generally important to form the silicon nitride layer by a low pressure-chemical vapor deposition (LP-CVD) method and not by a plasma enhanced-chemical vapor deposition (PE-CVD) method in order to have tensile stress instead of compressive stress. The compressive stress applied to a transistor decreases charge mobility of the transistor. Thus, the present embodiment is focused on preventing the decrease in charge mobility of the transistor by forming the silicon nitride layer having tensile stress.

The first insulation layer 124 is formed over the first stopping layer 123. The first insulation layer 124 includes an oxide-based material. The first insulation layer 124 and the first stopping layer 123 are etched to form second openings (not shown) one of which exposes the junction region of the first transistors (i.e., the source region) and another of which exposes one junction region (i.e., the drain region) of the second transistor. First and second contact plugs 125A and 125B are formed in the respective second openings.

Referring to FIG. 2B, a second insulation layer 127 and a second stopping layer 128 are formed over the resultant structure illustrated in FIG. 2A. The second stopping layer 128 includes an insulation material having an etch selectivity ratio to a subsequent third insulation layer 129. More particularly, the insulation material includes a nitride-based material such as silicon nitride. At this time, the silicon nitride layer is formed by a PE-CVD method. If the silicon nitride layer is formed by an LP-CVD method, the charge mobility of the transistors increases, but the quality of the second insulation layer 127 formed of an oxide-based material becomes unfavorable due to the increase of hydrogen. The quality deterioration of the second insulation layer results in deterioration of retention characteristic.

For reference, the reason that the hydrogen generation causes the quality deterioration of an insulation layer including an oxide-based material is because, generally, hydrogen forms weak ion bonds and thus, immunity to stress is low; and when hydrogen penetrates into the oxide-based layer, the quality of the oxide-based layer deteriorates easily by stress.

Therefore, in the present embodiment, by forming the second stopping layer 128 based on the typical PE-CVD method, the second stopping layer 128 can resolve the quality deterioration of the insulation material (e.g., oxide layer) and can make a thin layer formed above the first to fourth gate patterns PSSL, PCL, PDSL, and PLVP for various transistors exert tensile stress on the first to fourth gate patterns PSSL, PCL, PDSL, and PLVP. That is, the first stopping layer 123 formed nearer to the first through fourth gate patterns PSSL, PCL, PDSL, and PLVP has the tensile stress. Thus, the stress characteristic of the thin layer applied to the top of the transistors has the tensile stress overall. Therefore, a retention characteristic of the semiconductor device is improved and thereby increasing the charge mobility of the transistors.

The third insulation layer 129 includes an oxide-based material. The third insulation layer 129, the second stopping layer 128 and the second insulation layer 127 in the cell region CELL are patterned through a dual damascene process to form third openings 130A including a via hole and a trench that expose the respective first and second contact plugs 125A and 125B. At the same time, the third insulation layer 129, the second stopping layer 128, the second insulation layer 127, the first insulation layer 124, and the first stopping layer 123 in the peripheral region PERI are patterned to form fourth openings 130B including via holes and a trench that expose the respective first junction regions 121A and the fourth gate pattern PLVP.

Referring to FIG. 2C, a barrier layer 131 is formed over the resultant surface profile illustrated in FIG. 2B. The barrier layer 131 includes a refractory metal layer or a metal nitride layer that can prevent diffusion of copper and strengthen adhesion with the first to third insulation layers 124,127 and 129.

A metal layer 132 is formed over the barrier layer 131 to fill the third and fourth openings 130A, 130B. The metal layer 132 and the barrier layer 131 are subjected to chemical mechanical polishing (CMP) to form a plurality of first metal lines 133A, 133C, 133D, and 133E and a bit line 133B. The first metal line 133A is electrically coupled to the first contact plug 125A, arranged in parallel to the bit line 133B, and couples the first contact plug 125A to the peripheral region PERI.

A fourth insulation layer 135 is formed over the third insulation layer 129 including the first metal lines 133A, 133C, 133D, and 133E and the bit line 133B. Forming an extra stopping layer can be omitted prior to forming the fourth insulation layer 135. This omission is to make the layer formed above the first to fourth gate patterns PSSL, PCL, PDSL, and PLVP thin. The reason for forming the extra stopping layer after forming the first metal lines 133A, 133C, 133D, and 133E and the bit line 133B is to minimize damage of the first metal lines 133A, 133C, 133D, and 133E and the bit line 133B.

The fourth insulation layer 135 is etched to form fifth openings (not shown) that expose the first metal lines 133A and 133E and the bit line 133B. A plurality of second metal lines 139 fill the fifth openings. At this time, each of the second metal lines 139 is formed in a structure laminated with another barrier layer 137 and another metal layer 138.

According to various embodiments of the present invention, the first stopping layer, which includes a nitride-based material and is formed close to the gate patterns for various transistors, is formed by a LP-CVD method in order to have tensile stress. Thus, the transistors are exerted with the tensile stress in overall. Accordingly, charge mobility of the transistors increases. Also, the second stopping layer, which includes a nitride-based material and is formed above the first stopping layer, is formed by a PE-CVD method to have compressive stress. Thus, the quality of the first and second insulation layers including an oxide-based material is not degraded. Accordingly, a retention characteristic of the semiconductor device is improved.

While the present invention has been described with respect to the specific embodiments, it will be apparent to those skilled in the art that various changes and modifications may be made without departing from the spirit and scope of the invention as defined in the following claims. Particularly, in the specific embodiment, a NAND flash memory device is used as an example but it can be applied to all semiconductor memory device equipping transistor and nitride layer-based thin film.

What is claimed is:

1. A method for fabricating a semiconductor device, the method comprising:
forming a plurality of memory cells and transistors over a substrate;
forming a first stopping layer having tensile stress over the plurality of memory cells and transistors;
forming a first insulation layer over the substrate and the first stopping layer; and
forming a second stopping layer having compression stress over the first insulation layer.

2. The method of claim 1, wherein forming the first stopping layer comprises performing a low pressure chemical vapor deposition method.

3. The method of claim 2, wherein forming the second stopping layer comprises performing a plasma enhanced chemical vapor deposition method.

4. The method of claim 3, wherein the first insulation layer includes an oxide-based material.

5. The method of claim 4, wherein each of the first stopping layer and the second stopping layer includes a nitride-based material.

6. The method of claim 5, wherein each of the first and second stopping layers includes a silicon nitride layer.

7. The method of claim 1, further comprising, after forming the first insulation layer:
etching the first insulation layer and the stopping layer to form first and second openings; and
filling the first and second openings to form first and second contact plugs.

8. The method of claim 7, wherein the first contact plug is coupled to a common junction region between two of the transistors and the second contact plug is coupled to a junction region pertained to one of the transistors, the common junction region including a common source region and the junction region including a drain region.

9. The method of claim 7, further comprising, after forming the second stopping layer:
forming a second insulation layer over the second stopping layer;
etching the second insulation layer and the second stopping layer to form third openings exposing the first and second contact plugs; and
filling the third openings to form first metal lines.

10. The method of claim 9, further comprising, after forming the first metal lines:
forming a third insulation layer over the resultant structure obtained after forming the first metal lines;
etching the third insulation layer to form fourth openings exposing a group of the first metal lines; and
filling the fourth openings to form second metal lines.

11. A method for fabricating a semiconductor device, the method comprising:
forming a plurality of memory cells and transistors over a substrate;
forming a first nitride-based layer having tensile stress over the plurality of memory cells and transistors, the first nitride-based layer formed by a low pressure chemical vapor deposition method;
forming a first insulation layer over the substrate and the first stopping layer; and
forming a second nitride-based layer having compression stress over the first insulation layer, the second nitride-based layer formed by a plasma enhanced chemical vapor deposition method,
wherein the first and second nitride-based layers have an etch selectivity ratio to the first insulation layer.

12. The method of claim 11, wherein the first insulation layer includes an oxide-based material.

13. The method of claim 12, wherein each of the first and second stopping layers includes a nitride-based material.

14. The method of claim 13, wherein each of the first and second stopping layers includes a silicon nitride layer.

15. The method of claim 11, further comprising, after forming the first insulation layer:
etching the first insulation layer and the stopping layer to form first and second openings; and
filling the first and second openings to form first and second contact plugs.

16. The method of claim 15, wherein the first contact plug is coupled to a common junction region between two of the transistors and the second contact plug is coupled to a junction region pertained to one of the transistors, the common junction region including a common source region and the junction region including a drain region.

17. The method of claim 15, further comprising, after forming the second stopping layer:
forming a second insulation layer over the second stopping layer;
etching the second insulation layer and the second stopping layer to form third openings exposing the first and second contact plugs; and
filling the third openings to form first metal lines.

18. The method of claim 17, further comprising, after forming the first metal lines:
forming a third insulation layer over the resultant structure obtained after forming the first metal lines;
etching the third insulation layer to form fourth openings exposing a group of the first metal lines; and
filling the fourth openings to form second metal lines.
